(19) United States
(12) Patent Application Publication
(10) Pub. No.: US 2015/0044875 A1
(43) Pub. Date: Feb. 12, 2015

(54) METHOD OF FORMING PATTERN

(71) Applicant: United Microelectronics Corp., Hsinchu (TW)

(72) Inventor: Yu-Cheng Tung, Kaohsiung City (TW)

(73) Assignee: United Microelectronics Corp., Hsinchu (TW)

(21) Appl. No.: 13/963,631

(22) Filed: Aug. 9, 2013

(51) Int. Cl. H01L 21/308; H01L 21/033; G03F 1/68

(52) U.S. Cl. CPC H01L 21/3081; G03F 1/68; H01L 21/0338
USPC 438/703; 355/77

(57) ABSTRACT

A method of forming a pattern is disclosed. First, N kinds of different photomask patterns are provided. Thereafter, the N kinds of different photomask patterns are transferred to a hard mask layer by using at least N−1 kinds of light sources with different wavelengths, so as to form a hard mask pattern, wherein one of the at least N−1 kinds of light sources with different wavelengths is a light source with a wavelength of 193 nm, and N is an integer of three or more.

### BACKGROUND OF THE INVENTION

1. Field of Invention

The present invention relates to a semiconductor process, and more particularly to a method of forming a pattern.

2. Description of Related Art

As the stacked density of semiconductor devices is increased, the requirement for the critical dimension (CD) of a device is getting strict. In order to fabricate a small-dimension device, the use of advanced lithography techniques for patterning is an inevitable trend. However, if all of the lithography processes are performed through advanced lithography techniques, the cost spent on purchasing new machines is high.

### SUMMARY OF THE INVENTION

The present invention provides a method of forming a pattern, in which the required pattern can be formed by the existing low-level machines in combination with advanced lithography techniques.

The present invention further provides a method of forming a pattern, by which the process cost can be reduced.

The present invention provides a method of forming a pattern. First, N kinds of different photomask patterns are provided. Thereafter, the N kinds of different photomask patterns are transferred to a hard mask layer by using at least N−1 kinds of light sources with different wavelengths, so as to form a hard mask pattern, wherein one of the at least N−1 kinds of light sources with different wavelengths is a light source with a wavelength of 193 nm, and N is an integer of three or more.

According to an embodiment of the invention, another of the at least N−1 kinds of light sources with different wavelengths is a light source with a wavelength of 436 nm (G-line), a light source with a wavelength of 365 nm (I-line), a light source with a wavelength of 248 nm or a light source with a wavelength shorter than 193 nm.

According to an embodiment of the invention, the hard mask pattern has at least N−1 kinds of patterns with different line widths.

According to an embodiment of the invention, the hard mask pattern includes a first hard mask pattern and a second hard mask pattern, and a dimension of the first hard mask pattern is less than a dimension of the second hard mask pattern.

According to an embodiment of the invention, the method further includes forming a sacrificial layer on the hard mask layer, wherein a method of forming the first hard mask pattern includes the following steps. A first patterned mask layer is formed on the sacrificial layer by using a first photomask and a first light source with a wavelength of 193 nm. A first etching process is performed to transfer patterns of the first patterned mask layer to the sacrificial layer, so as to form at least one mandrel pattern. A spacer loop is formed around the mandrel pattern. The mandrel pattern is removed. A second patterned mask layer is formed by using a second photomask and a second light source, wherein the second patterned mask layer has an opening to expose a portion of the spacer loop at an end of the mandrel pattern. A second etching process is performed by using the second patterned mask layer as a mask, so as to break the spacer loop and form a plurality of spacers. A third etching process is performed to the hard mask layer by using the plurality of spacers as a mask, so as to form the first hard mask pattern.

According to an embodiment of the invention, a method of forming the second hard mask pattern includes the following steps. A third patterned mask layer is formed on the hard mask layer by using a third photomask and a third light source. Thereafter, the third etching process is performed to the hard mask layer by using the third patterned mask layer as a mask, so as to form the second hard mask pattern.

According to an embodiment of the invention, the step of forming the third patterned mask layer is performed after the second etching process.

According to an embodiment of the invention, the step of forming the third patterned mask layer is performed before the step of forming the second patterned mask layer.

According to an embodiment of the invention, the second hard mask pattern is adjacent to and in contact with the first hard mask pattern.

According to an embodiment of the invention, the hard mask pattern further includes a third hard mask pattern spaced apart from the first hard mask pattern by a distance.

According to an embodiment of the invention, the second hard mask pattern is spaced apart from the first hard mask pattern by a distance.

According to an embodiment of the invention, the method further includes patterning a material layer under the hard mask pattern by using the hard mask pattern as a mask.

The present invention further provides a method of forming a pattern. First, a target pattern of a material layer is into a plurality of partial patterns. A mandrel pattern is formed between first partial patterns with a smallest critical dimension among the partial patterns by using a first light source, and at least one second partial pattern is formed among the partial patterns by using at least one second light source, wherein a wavelength of the first light source is less than a wavelength of the second light source, and one of the first and second light sources is a light source with a wavelength of 193 nm.

According to an embodiment of the invention, another of the first and second light sources is a light source with a wavelength of 436 nm (G-line), a light source with a wavelength of 365 nm (I-line), a light source with a wavelength of 248 nm or a light source with a wavelength shorter than 193 nm.

The present invention also provides a method of forming a pattern. First, a target pattern of a material layer is into a plurality of partial patterns. A mandrel pattern is formed between first partial patterns with a smallest critical dimension among the partial patterns by using a wet model 193 nm light source, and at least one second partial pattern is formed among the partial patterns by using at least one dry model light source.

According to an embodiment of the invention, the dry model light source is a dry model 193 nm light source, a dry model 436 nm light source, a dry model 365 nm light source, or a dry model 248 nm light source.

In view of the above, in the pattern forming method of the invention, the required pattern can be formed by the existing low-level machines in combination with advanced lithography techniques. Therefore, the process cost can be reduced.

In order to make the aforementioned and other objects, features and advantages of the present invention comprehensible, a preferred embodiment accompanied with figures is described in detail under.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H illustrate top views of a method of forming a pattern according to a first embodiment of the present invention.

FIG. 2A to FIG. 2H illustrate cross-sectional views taken along the line I-I of FIG. 1A to FIG. 1H.

FIG. 3A to FIG. 3H illustrate top views of a method of forming a pattern according to a second embodiment of the present invention.

FIG. 4A to FIG. 4H illustrate cross-sectional views taken along the line II-II of FIG. 3A to FIG. 3H.

FIG. 5 to FIG. 7 are respective schematic views of first, second and third photomasks.

FIG. 8 illustrates a partial process flow of a method of forming a pattern according to the first embodiment of the present invention.

FIG. 9 illustrates a partial process flow of a method of forming a pattern according to the second embodiment of the present invention.

FIG. 10 illustrates a schematic view of a patterned material layer constituted by partial patterns.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the present invention, multiple exposure processes are performed by using light sources with different wavelengths and multiple photomasks, so as to transfer patterns of the photomasks to a wafer.

FIG. 10 illustrates a schematic view of a patterned material layer constituted by partial patterns.

Referring to FIG. 10, in the invention, a target pattern of a patterned material layer 101d is divided into a plurality of partial patterns including patterns 101a, 101b and 101c, wherein the patterns 101a and 101b are block patterns, and each of the patterns 101c is a strip pattern having a corner (i.e. an L-shaped pattern). The pattern 101a and each of the patterns 101c are spaced apart from one another by a distance. Each of the patterns 101b is adjacent to and in contact with the corresponding pattern 101c. According to the critical dimensions of the patterns 101a, 101b and 101c on the wafer, the light sources with different wavelengths are selected and the different photomasks are designed upon the requirements, so as to form the respective partial patterns (e.g. patterns 101a, 101b and 101c) which constitute the required target pattern of the patterned material layer 101d.

More specifically, the partial patterns with the smallest critical dimension (e.g. the pattern 101c) can be fabricated by using the most advanced exposure machine to create mandrel patterns 110a, forming spacer loops and then breaking the spacer loops. On the other hand, the partial patterns with a greater critical dimension (e.g. the patterns 101a and 101b) are formed by using the low-level machines.

Two embodiments are provided below to illustrate a method of forming a pattern of the invention.

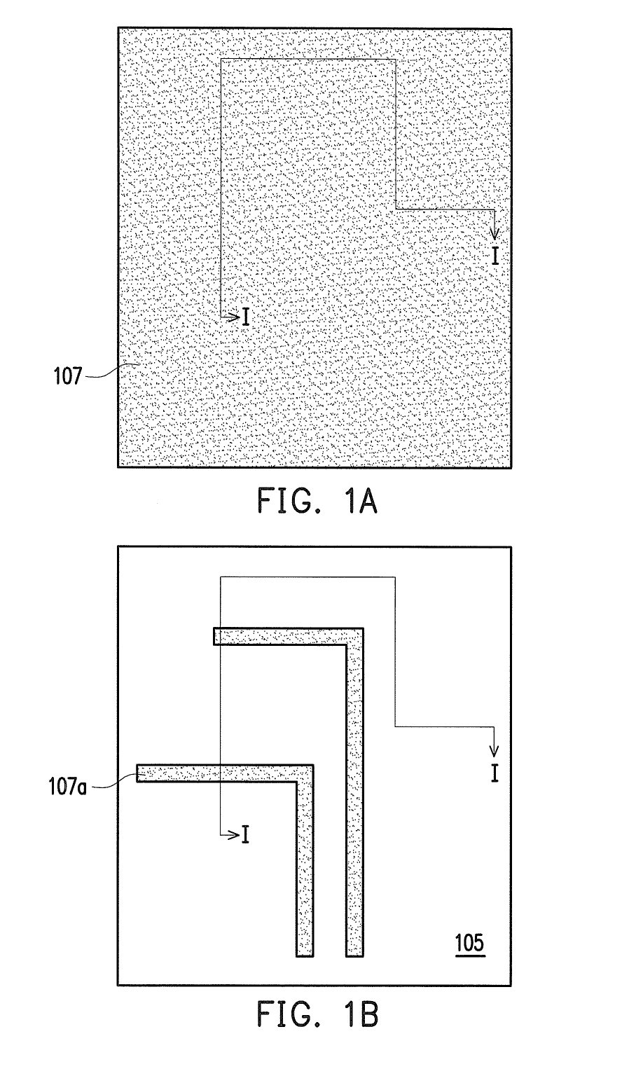

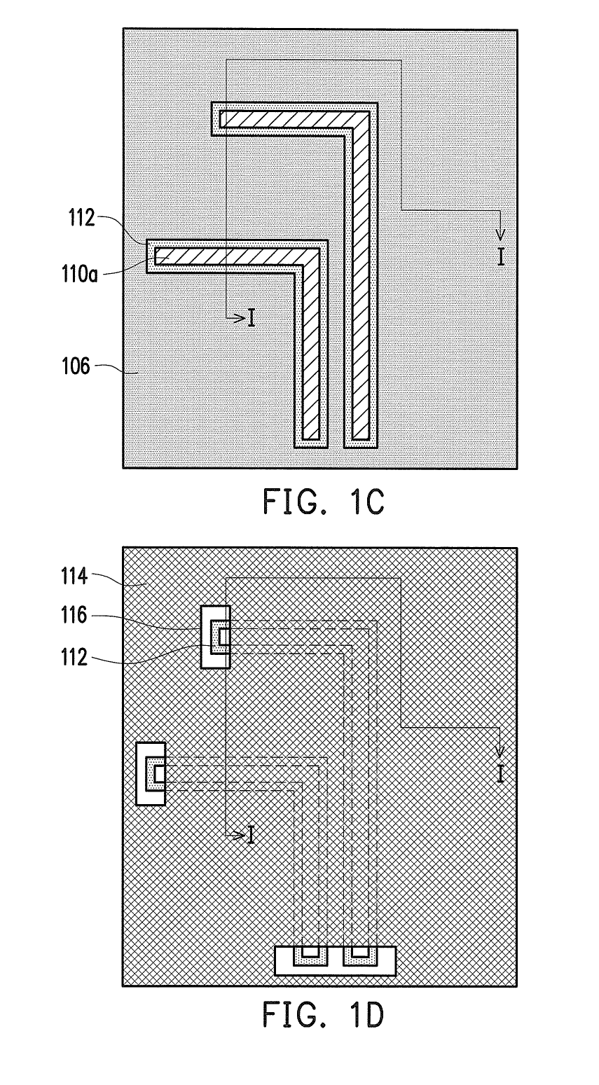

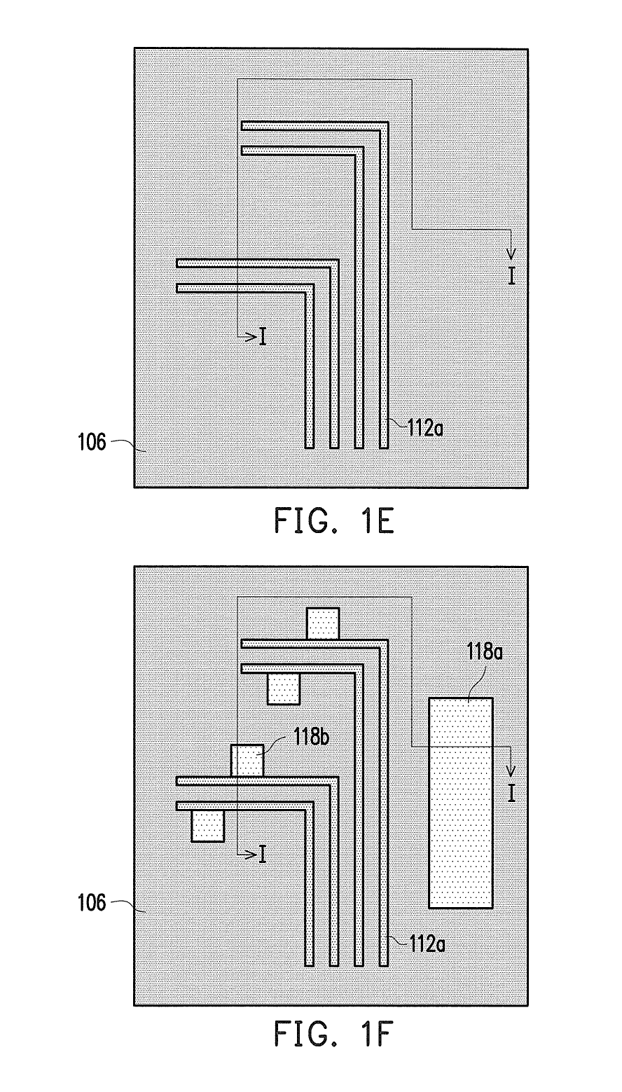

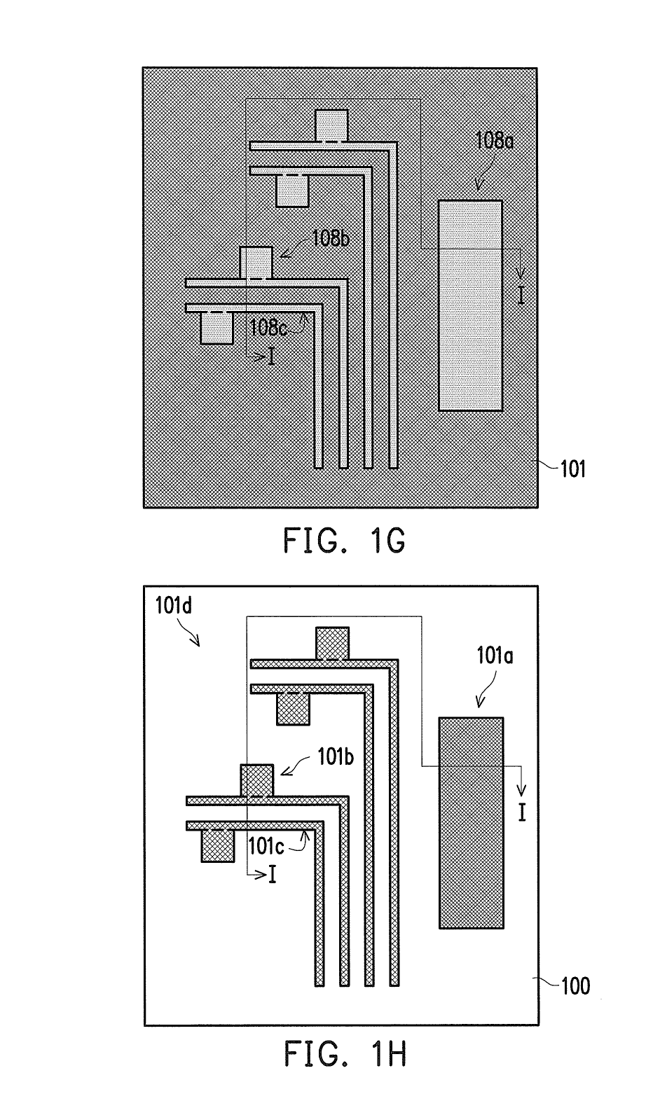

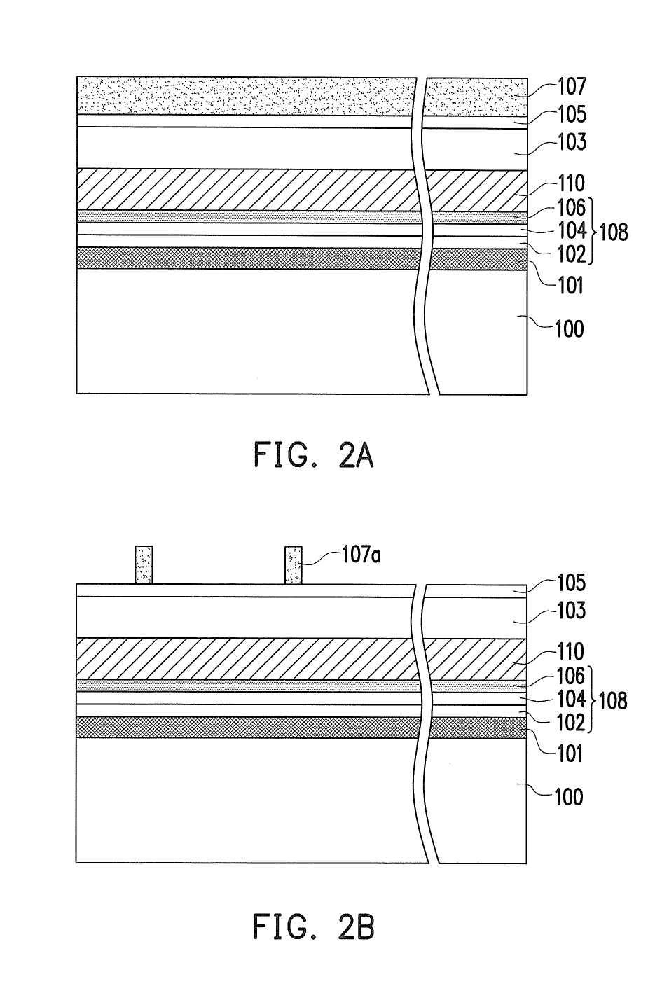

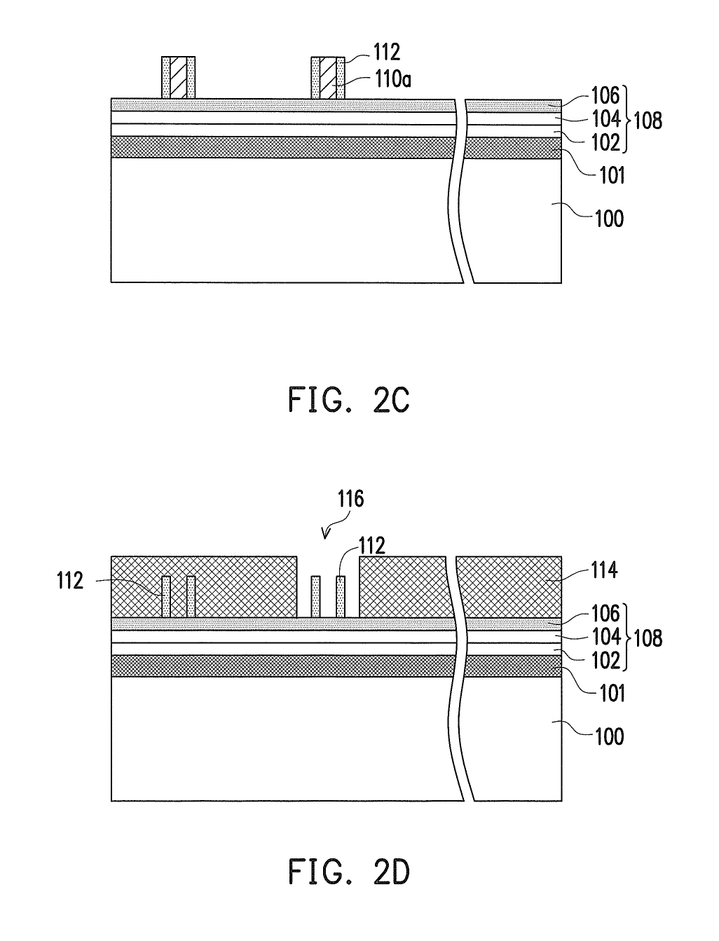

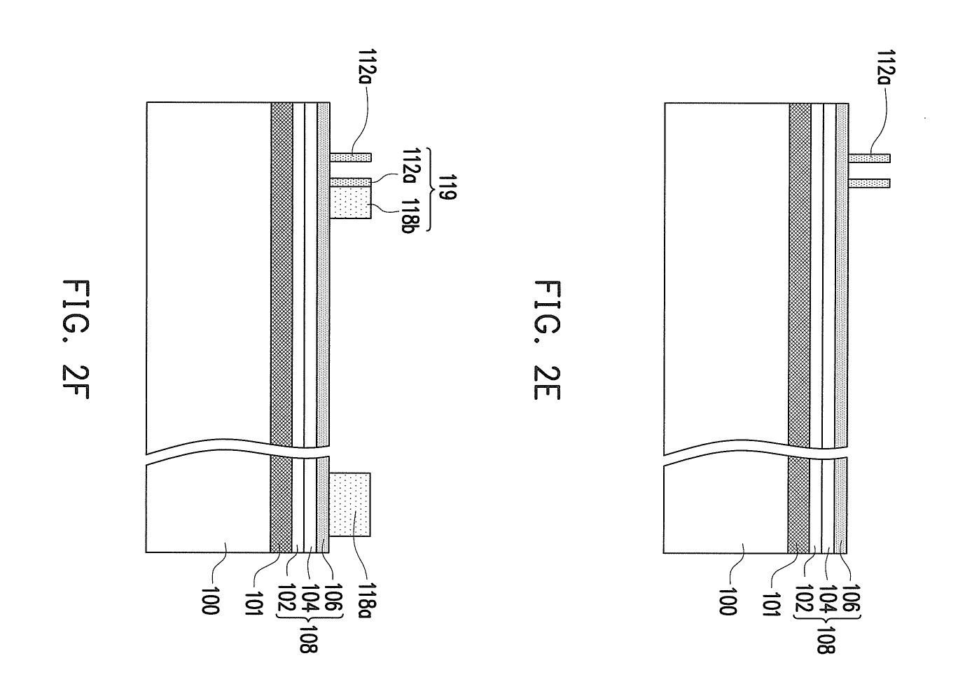

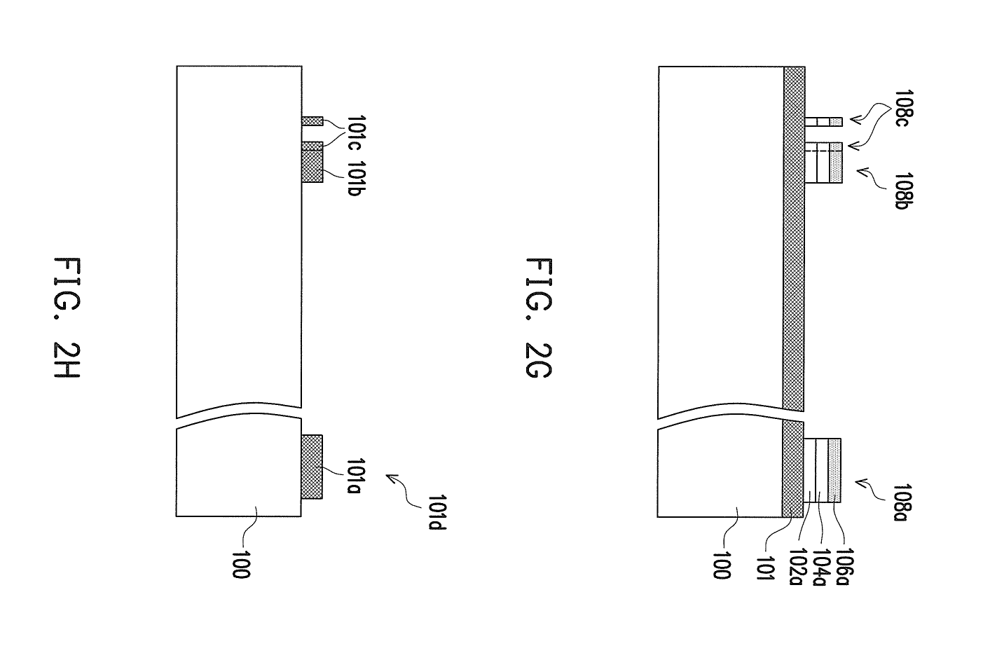

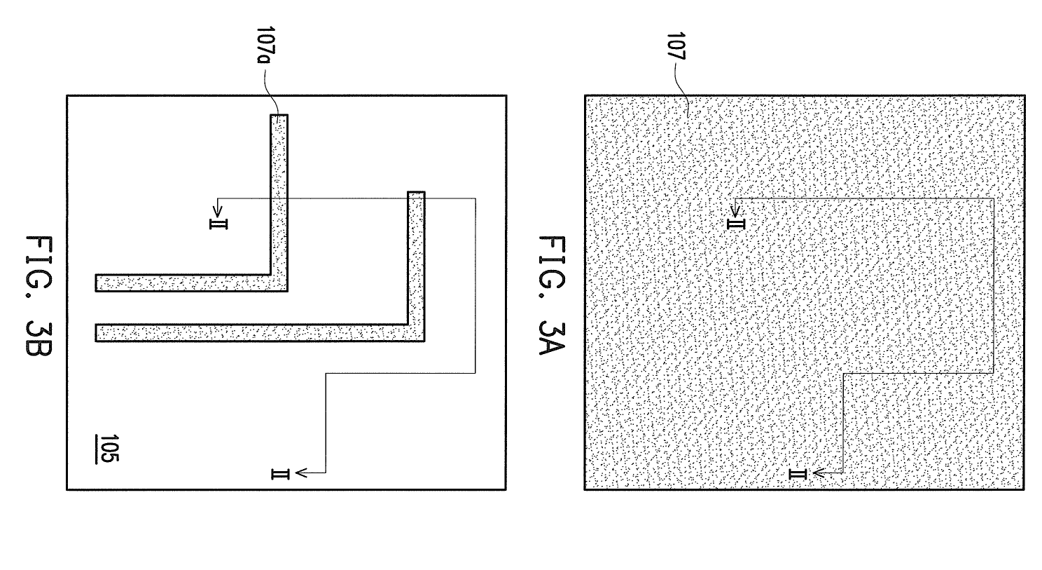

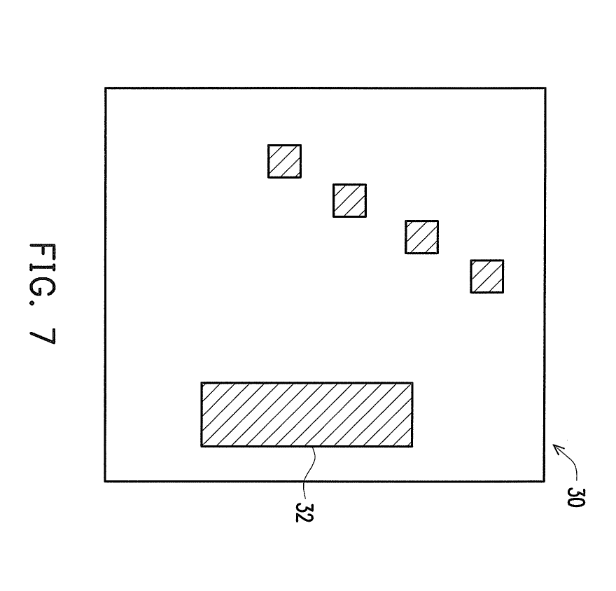

FIG. 1A to FIG. 1H illustrate top views of a method of forming a pattern according to a first embodiment of the present invention. FIG. 2A to FIG. 2H illustrate cross-sectional views taken along the line I-I of FIG. 1A to FIG. 1H. FIG. 5 to FIG. 7 are respective schematic views of first, second and third photomasks. FIG. 8 illustrates a partial process flow of a method of forming a pattern according to the first embodiment of the present invention.

Referring to FIG. 1A and FIG. 2A, a material layer 101, a hard mask layer 108 and a sacrificial layer 110 are sequentially formed on a substrate 100. The substrate 100 can be a semiconductor substrate, such as a silicon-containing substrate. The material layer 101 can be a dielectric layer, a conductive layer or a film to be patterned. In another embodiment, the material layer 101 is not present on the substrate 100. That is, the substrate 100 is the film to be patterned, and the hard mask layer 108 and the sacrificial layer 110 are directly formed on the substrate 100. The hard mask layer 108 can be a single layer or a multi-layer structure. In this embodiment, the hard mask layer 108 includes, from bottom to top, a first oxide layer 102, a nitride layer 104 and a second oxide layer 106. The first oxide layer 102 includes silicon oxide. The nitride layer 104 includes silicon nitride. The second oxide layer 106 includes silicon oxide. The sacrificial layer 110 can be an amorphous silicon layer, a polysilicon layer or a material layer having an etching selectivity different from that of the underlying hard mask layer 108. The method of forming each of the first oxide layer 102, the nitride layer 104, the second oxide layer 106 and the sacrificial layer 110 includes performing a chemical vapor deposition (CVD) process or a suitable deposition process.

Thereafter, a mask layer 107 is formed on the sacrificial layer 110. In an embodiment, an anti-reflection coating (ARC) layer 103 and a bottom anti-reflection coating (BARC) layer 105 can be formed prior to the formation of the mask layer 107. The ARC layer 103 can be a single-layer structure, a double-layer structure or a multi-layer structure. The BARC layer 105 can be a single-layer structure, a double-layer structure or a multi-layer structure. The mask layer 107 can be a photoresist layer.

Referring to FIG. 1B, FIG. 2B, FIG. 5 and FIG. 8, a step 810 is implemented, in which an exposure process is performed to the mask layer 107 (see FIGS. 1A and 2A) by using a first photomask 10 having patterns 12 (see FIG. 5) and a first light source. Thereafter, the exposed mask layer 107 is developed to form the patterned mask layer 107a. When the patterns 12 of the first photomask 10 are made by a light-shielding material and surrounded by a transparent material, the mask layer 107 includes a positive photoresist material. On the contrary, when the patterns 12 of the first photomask 10 are made by a transparent material and surrounded by a light-shielding material, the mask layer 107 includes a negative photoresist material. In an embodiment, the step of forming the patterned mask layer 107a can be implemented by an immersion lithography technique. More specifically, in the immersion lithography technique, the first light source is a light source with a wavelength of 193 nm, which may be generated by an ArF excimer laser. 193 nm light source can be a dry model 193 nm light source or a wet model 193 nm light source. Generally, a wet model 193 nm light source (or called 193 nm immersion) is used to define the smallest critical dimension. The mask layer 107 can include a positive or negative photoresist material for a 193 nm light source. The exposure process is performed by an immersion scanner. In another embodiment, the step of forming the patterned mask layer 107a can be implemented by a more advanced lithography technique. In the more advanced lithography technique, the first light source is a light source with a wavelength shorter than 193 nm, which may be generated by an extreme ultraviolet laser, an X-ray or an electron beam. The mask layer 107 can include a positive or negative photoresist material for a light source with a wavelength shorter than 193 nm.

Referring to FIG. 1C and FIG. 2C, an etching process is performed by using the patterned mask layer 107a (see FIGS. 1A and 2A) as a mask, so as to pattern the sacrificial layer 110 and form a plurality of mandrel patterns (or called core patterns) 110a. The etching process can be an anisotropic etching process, such as a dry etching process. Thereafter, the patterned mask layer 107a and the underlying ARC layer 103 and BARC layer 105 are removed to expose the mandrel pattern 110a.

Thereafter, a spacer loop 112 is formed on the sidewall of each mandrel pattern 110a. The spacer loops 112 include silicon nitride. The method of forming the spacer loops 112 includes forming a spacer material layer on the substrate 100 covering the mandrel patterns 110a, and then performing an anisotropic dry etching process to remove a portion of the spacer material layer. In an embodiment, from a top view, each of the spacer loops 112 surrounding the corresponding mandrel pattern 110a.

Referring to FIG. 1D and FIG. 2D, the mandrel patterns 110a (see FIG. 1C and FIG. 2C) are removed to expose the spacer loops 112. Afterwards, a patterned mask layer 114 is formed on the substrate 100. The method of forming the patterned mask layer 114 includes forming a mask layer on the substrate 100. The mask layer includes a photoresist material. Then, a step 820 of FIG. 8 is implemented, in which an exposure process is performed to the mask layer by using the second photomask 20 having patterns 22 (see FIG. 6) and a second light source. Thereafter, the exposed mask layer is developed to form the patterned mask layer 114. In this embodiment, the patterned mask layer 114 has openings 116 to expose a portion of the spacer loops at ends of the mandrel patterns 110a. When the patterns 22 of the second photomask 20 are opening patterns made by a transparent material and surrounded by a light-shielding material, the mask layer includes a positive photoresist material. On the contrary, when the patterns 22 of the second photomask 20 are made by a light-shielding material and surrounded by a transparent material, the mask layer includes a negative photoresist material. The wavelength of the second light source can be selected depending on the critical dimension of the openings 116. The second light source can be a dry model light source or a wet model light source. The wavelength of the second light source can be the same as, greater than or shorter than the wavelength of the first light source. The second light source can have a wavelength equal to, longer than or shorter than 193 nm. For example, the second light source can be a dry model light source with a wavelength of 436 nm (G-line), a dry model light source with a wavelength of 365 nm (I-line), a dry model light source with a wavelength of 248 nm (e.g. KrF excimer laser), a light source with a wavelength of 193 nm (e.g. KrF excimer laser), an extreme ultraviolet laser, an X-ray or an electron beam. In this embodiment, the patterned mask layer 107a can be formed with a 193 nm light source. The critical dimension of the openings 116 of the patterned mask layer 114 is greater than the critical dimension of the patterned mask layer 107a, so that the patterned mask layer 114 can be formed through a light source with a wavelength longer than 193 nm.

Referring to FIG. 1E and FIG. 2E, an etching process is performed by using the patterned mask layer 114 as a mask, so as to remove the spacer loops 112 exposed by the openings 116, break the spacer loops 112 and form spacers 112a. The etching process can be an anisotropic etching process, such as a dry etching process. Thereafter, the patterned mask layer 114 is removed to expose the spacers 112a.

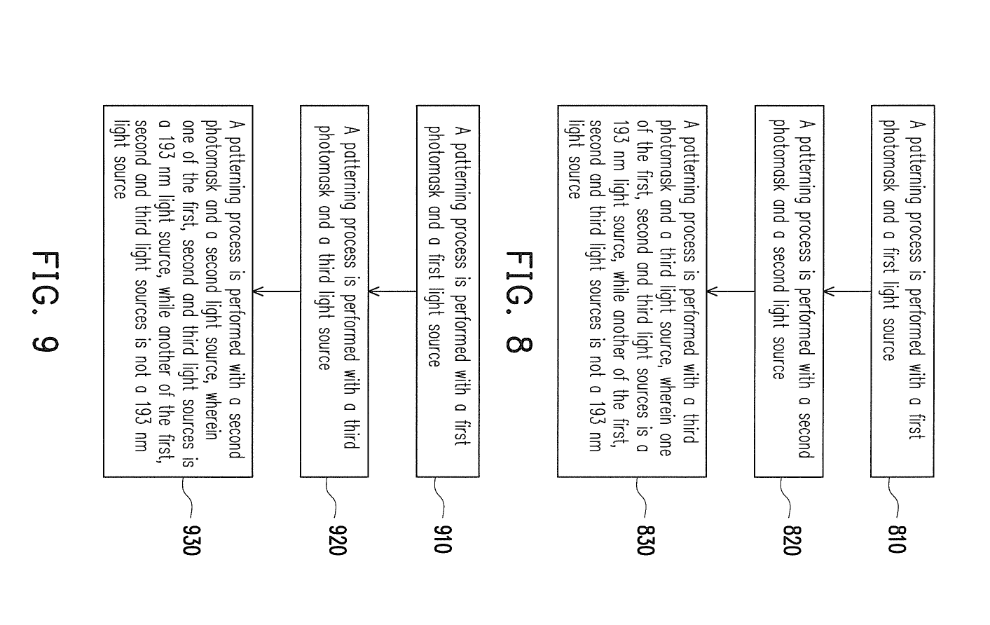

Referring to FIG. 1F and FIG. 2F, patterned mask layers 118a and 118b are formed on the substrate 100. The patterned mask layer 118a is spaced apart from the spacers 112a by a distance. The patterned mask layer 118b contacts the spacer loops to form a combined mask 119. The method of forming the patterned mask layers 118a and 118b includes forming a mask layer on the substrate 100. The mask layer includes a photoresist material. Thereafter, a step 830 of FIG. 8 is implemented, in which an exposure process is performed to the mask layer by using a third photomask 30 having patterns 32 (see FIG. 7) and a third light source. Afterwards, the exposed mask layer is developed to form the patterned mask layers 118a and 118b as shown in FIG. 1F and FIG. 2F. When the patterns 32 of the photomask 30 are made by a light-shielding material and surrounded by a transparent material, the mask layer includes a positive photoresist material. When the patterns 32 of the photomask 30 are made by a transparent material and surrounded by a light-shielding material, the mask layer includes a negative photoresist material. The third light source can be different from the first light source. The third light source has a wavelength longer than or shorter than 193 nm. The light source with a wavelength longer than 193 nm can be a 436 nm light source (G-line), a 365 nm light source (I-line) or a 248 nm light source (e.g. KrF excimer laser). The light source with a wavelength shorter than 193 nm can be an extreme ultraviolet laser, an X-ray or an electron beam. In this embodiment, the critical dimensions of the patterned mask layers 118a and 118b are greater than the critical dimension of the mandrel patterns 110a (see FIG. 1C), so that the patterned mask layers 118a and 118b can be formed by using a light source has a wavelength longer than 193 nm.

Referring to FIGS. 1G and 2G, the hard mask layer 108 is patterned to form a plurality of hard mask patterns 108a, 108b and 108c. In this embodiment, each of the hard mask patterns 108a, 108b and 108c includes, from bottom to top, a first oxide pattern 102a, a nitride pattern 104a and a second oxide pattern 106a. The method of patterning the hard mask layer 108 includes performing a dry etching process by using the patterned mask layers 118a and 118b and the spacers 112a as a mask, so as to form a hard mask pattern 108a under the patterned mask layer 118a, form hard mask patterns 108b below the patterned mask layer 118a, and form hard mask patterns 108c below the spacers 112a. The patterned mask layers 118a and 118b and the spacers 112a can be removed during the dry etching process or can be removed by another etching process.

In the said embodiment of the invention, the line width of the hard mask patterns 108b is greater than the line width of the hard mask patterns 108c while less than the line width of the hard mask pattern 108a. However, the present invention is not limited thereto. The line widths of the hard mask patterns 108a, 108b and 108c can be designed according to the required sizes and patterns in the actual use.

Referring to FIG. 1H and FIG. 2H, the material layer 101 is patterned by using the hard mask patterns 108a, 108b and 108c as a mask, so as to form a patterned material layer 101d including patterns 101a, 101b and 101c respectively below the hard mask patterns 108a, 108b and 108c. The method of patterning the material layer 101 includes performing a dry etching process. Thereafter, the hard mask patterns 108a, 108b and 108c are removed to expose the patterns 101a, 101b and 101c of the patterned material layer 101d. In this embodiment, the line with of the patterns 101b is less than the line width of the pattern 101a while greater than the line width of the patterns 101c. However, the present invention is not limited thereto.

In the said embodiment, the step of forming the patterned mask layers 118a and 118b (see step 830, FIG. 1F, FIG. 2F) for defining the wider hard mask patterns 108a and 108b is performed after the step of breaking the spacer loops 112 with photolithography and etching processes (see step 820, FIG. 1D, FIG. 2D, FIG. 1E and FIG. 2E), but the present invention is not limited thereto. In another embodiment, the step of forming the patterned mask layers 118a and 118b for defining the wider hard mask patterns 108a and 108b can be performed after the step of forming the spacer loops 112 and before the step of breaking the spacer loops 112 with photolithography and etching processes.

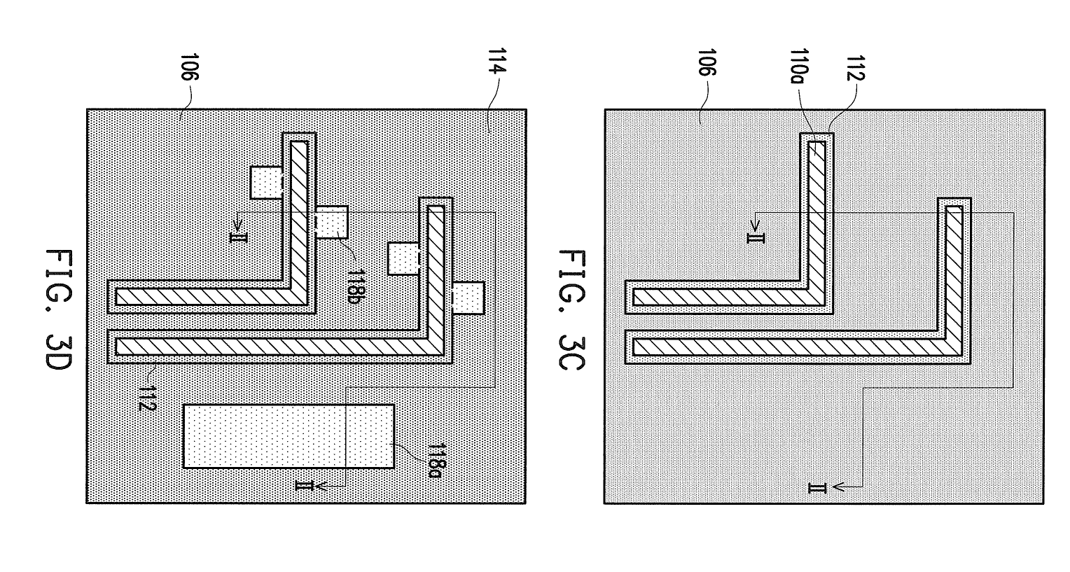

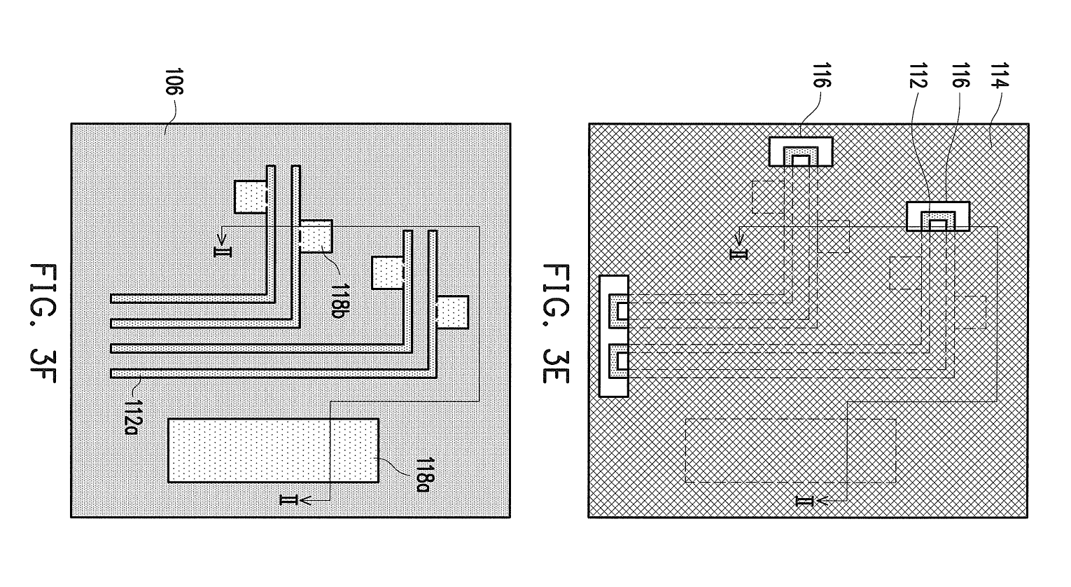

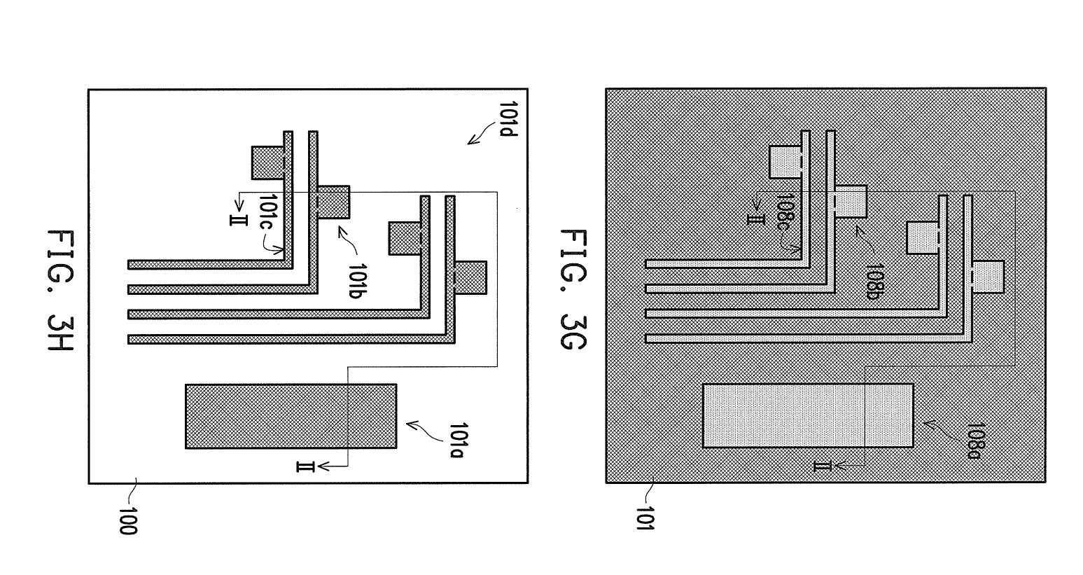

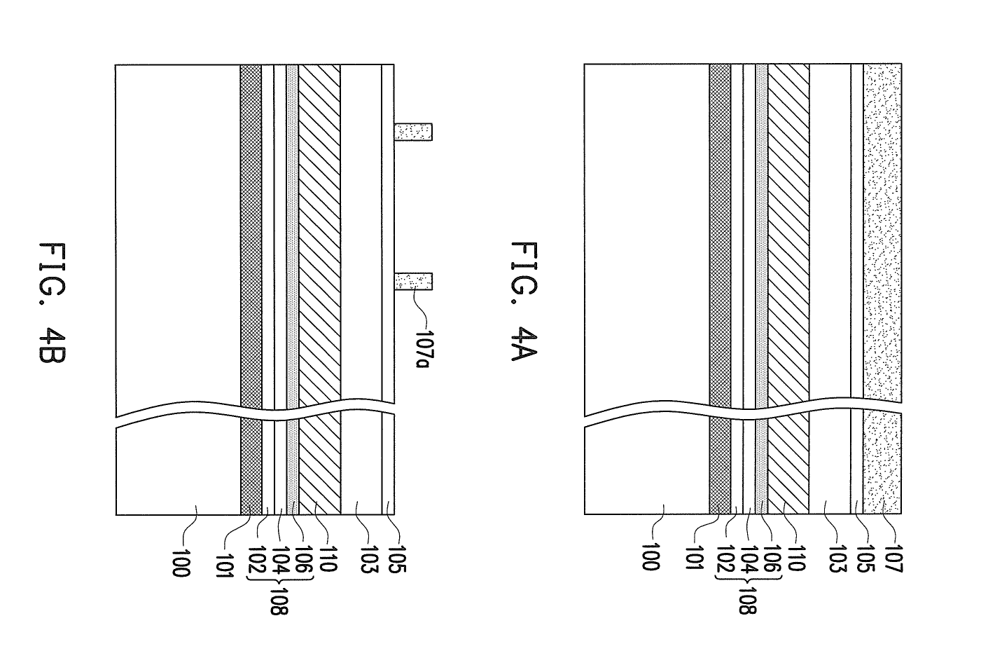

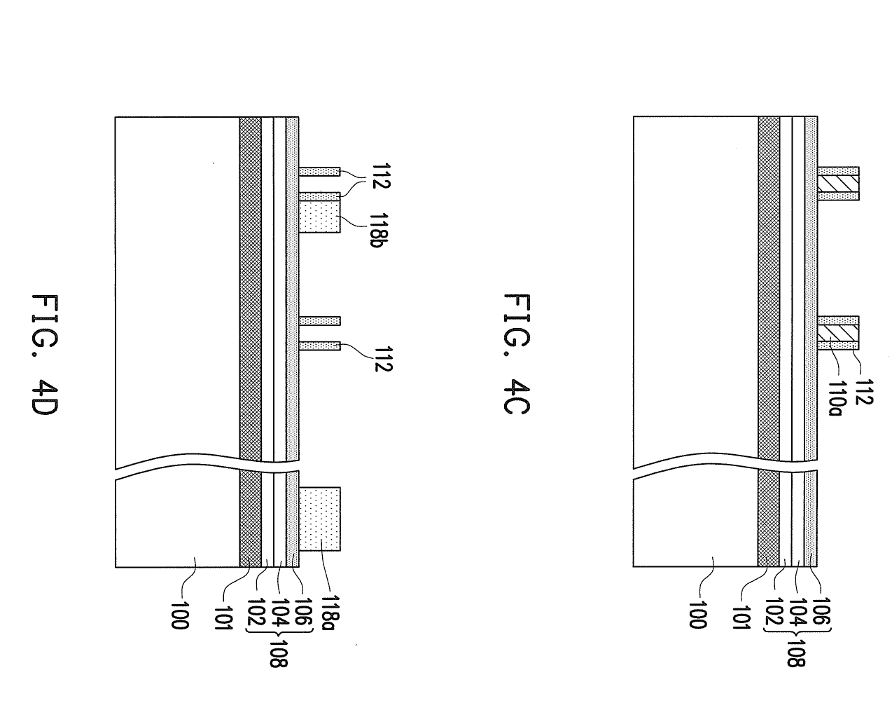

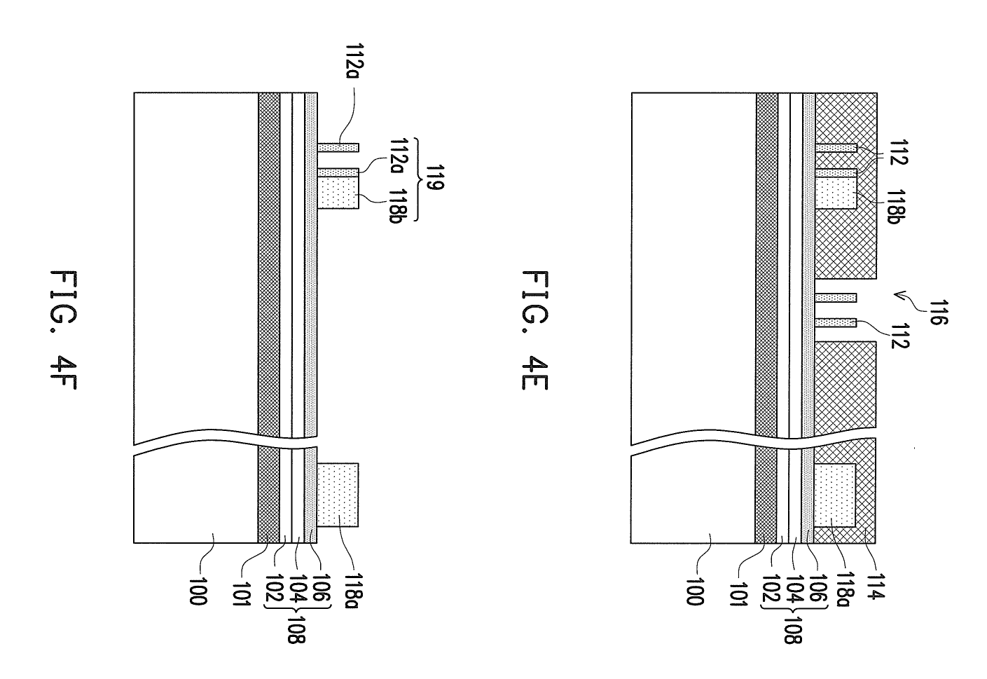

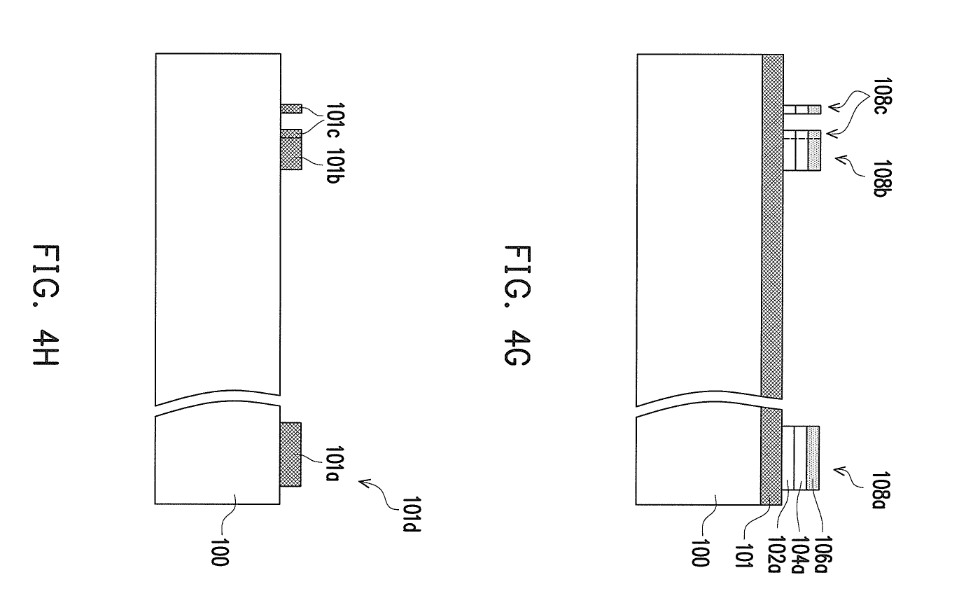

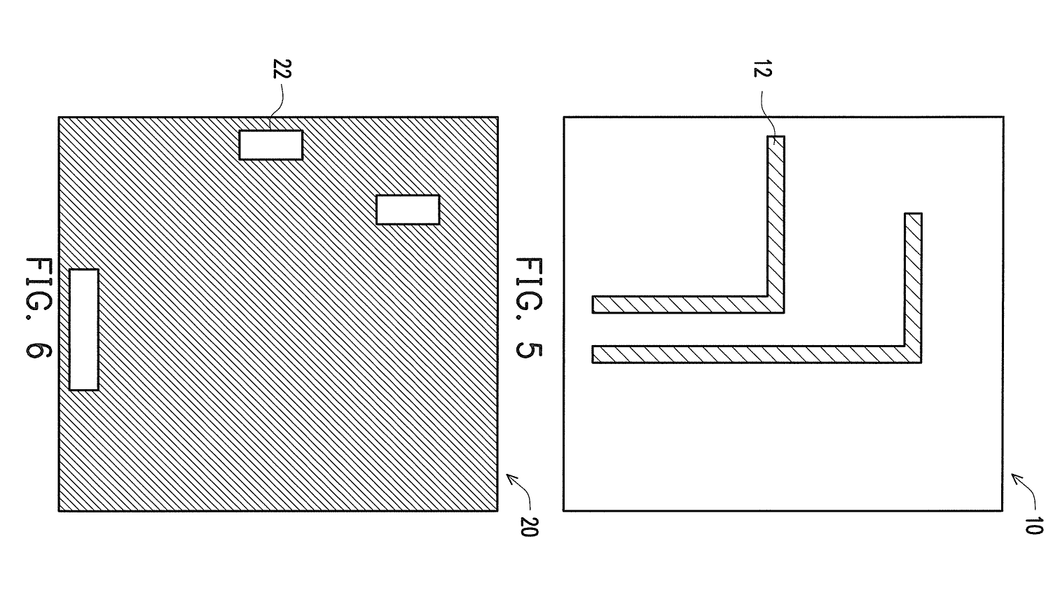

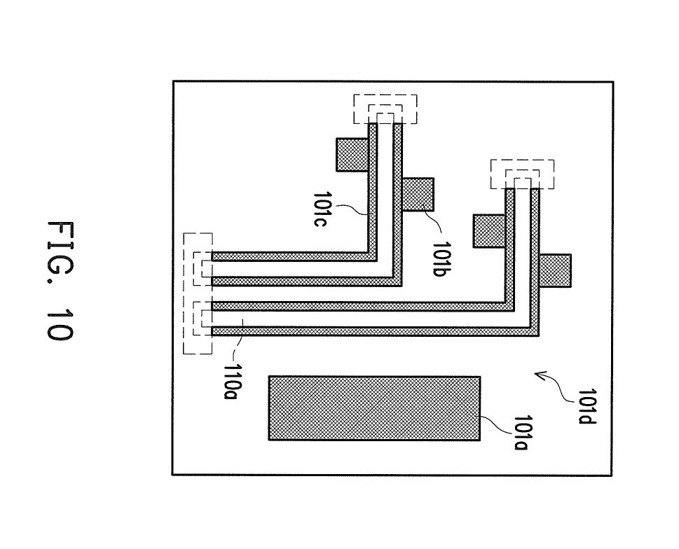

FIG. 3A to FIG. 3H illustrate top views of a method of forming a pattern according to a second embodiment of the present invention. FIG. 4A to FIG. 4H illustrate cross-sectional views taken along the line II-II of FIG. 3A to FIG. 3H. FIG. 9 illustrates a partial process flow of a method of forming a pattern according to the second embodiment of the present invention.

Referring to FIGS. 3A-3C and FIGS. 4A-4C, an intermediate structure is formed according to the disclosed method of FIGS. 1A-1C and FIGS. 2A-2C. The intermediate structure has a plurality of mandrel patterns 110a. The method of forming the mandrel patterns 110a includes performing an exposure process to the mask layer 107 by using the first photomask 10 having the patterns 12 (see FIG. 5) and the first light source (see FIG. 9, step 910), so as to form a patterned mask layer 107a. Therefore, an etching process is performed to pattern a sacrificial layer 110 by using the patterned mask layer 107a as a mask, so as to form the mandrel patterns 110a. Thereafter, a spacer loop 112a is formed to surround each of the mandrel patterns 110a.

Referring to FIG. 3D and FIG. 4D, the mandrel patterns 110a (see FIG. 3C and FIG. 4C) are removed. Thereafter, patterned mask layers 118a and 118b are formed on the substrate 100. The method of forming the patterned mask layers 118a and 118b includes forming a mask layer on the substrate 100. The mask layer can include a photoresist material. Afterwards, a step 920 of FIG. 9 is implemented, in which an exposure process is performed to the mask layer by using the third photomask 30 having the patterns 32 (see FIG. 7) and the third light source. The exposed mask layer is developed to form the patterned mask layers 118a and 118b as shown in FIG. 3D and FIG. 4D.

Referring to FIG. 3E and FIG. 4E, a patterned mask layer 114 is formed on the substrate 100. The method of forming the patterned mask layer 114 includes forming a mask layer on the substrate 100. The mask layer can include a photoresist material. Afterwards, a step 930 of FIG. 9 is implemented, in which an exposure process is performed to the mask layer by using the second photomask 20 having the patterns 22 (see FIG. 6) and the second light source. The exposed mask layer is developed to form the patterned mask layer 114 as shown in FIG. 3E and FIG. 4E. The patterned mask layer 114 has openings 116 to expose a portion of the spacer loops 112 at the ends of the mandrel patterns 110a.

Referring to FIGS. 3F and 4F, the spacer loops 112 exposed by the openings 116 are removed through an etching process by using the patterned mask layer 114 as a mask, so as to break the spacer loops 112 and form spacers 112a. Thereafter, the patterned mask layer 114 is removed to expose the spacers 112a and the patterned mask layers 118a and 118b. The patterned mask layer 118a is spaced apart from the spacers 112a by a distance. The patterned mask layer 118b contacts the spacers 112a to constitute a combined mask 119.

Referring to FIGS. 3G-3H and FIGS. 4G-4H, a hard mask layer 108 is patterned to form hard mask patterns 108a, 108b and 108c on the substrate 100. Thereafter, a material layer 101 is patterned by using the hard mask patterns 108a, 108b and 108c as a mask, so as to form a patterned material layer 101d including patterns 101a, 101b and 101c.

In the said embodiments described in FIGS. 1A-1H, FIGS. 2A-2H, FIGS. 3A-3H and FIGS. 4A-4H, the line width of the pattern 101a is greater than the line width of the patterns 101b, and the line width of the patterns 101b is greater than the line width of the patterns 101c.

The patterns 101c with the smallest critical dimension can be formed by the following steps. A patterned mask layer 107a is formed with a first photomask and a first light source. An etching process is performed by using the patterned mask layer 107a as a mask to form mandrel patterns 110a. Spacer loops 112 are formed to respectively surround the mandrel patterns 110a. The mandrel patterns 110a are removed. A patterned mask layer 114 is formed with a second photomask and a second light source. An etching process is performed by using the patterned mask layer 114 as a mask to break the spacer loops 112 and form spacers 112a. The patterns of the spacers 112a are transferred to the underlying hard mask layer 108 to form hard mask patterns 108c. A material layer 101 is patterned by an etching process with the hard mask patterns 108c as a mask, so as to form the patterns 101c with the smallest critical dimension.

The pattern 101a with the greatest critical dimension and the patterns 101b having a critical dimension between the critical dimensions of the patterns 101a and 101c can be formed by the following steps. Patterned mask layers 118a and 118b are formed with a third photomask and a third light source. An etching process is performed by using the patterned mask layers 118a and 118b as a mask to form hard mask patterns 108a and 108b. The material layer 101 is patterned by an etching process with the hard mask patterns 108a and 108b as a mask, so as to form the patterns 101a with the greatest critical dimension and the patterns 101b.

In an embodiment, the step of forming the patterned mask layers 118a and 118b can be performed after the step of breaking the spacer loops 112, but the present invention is not limited thereto. In another embodiment, the step of forming the patterned mask layers 118a and 118b can be performed after the step of forming the spacer loops 112 and before the step of breaking the spacer loops 112.

Referring to FIG. 2F and FIG. 4F, the said embodiments in which the line width of the patterned mask layer 118a is greater than the width of the combined mask 119 including the spacers 112a and the patterned mask layer 118a are provided for illustration purposes, and are not construed as limiting the present invention. In another embodiment, the line width of the patterned mask layer 118a can be less than the width of the combined mask 119 including the spacers 112a and the patterned mask layer 118a, wherein the line width of the patterned mask layer 118a is greater than the line width of the spacers 112a. In yet another embodiment, the line width of the patterned mask layer 118a can be less than the line width of the spacers 112a.

In the said embodiments, three kinds of different photomask patterns are transferred to a material layer on a substrate by using at least two kinds of light sources with different wavelengths, so as to form at least two patterns with different line widths. One of the at least two kinds of light sources with different wavelengths is a light source with a wavelength of 193 nm. However, the present invention is not limited thereto. In another embodiment, N kinds of different photomask patterns are provided, and the N kinds of different photomask patterns are transferred to a material layer on a substrate by using at least N−1 kinds of light sources with different wavelengths, so as to form at least N−1 kinds of patterns with different line widths. One of the at least N−1 kinds of light sources with different wavelengths is a light source with a wavelength of 193 nm, and N is an integer of three or more.

In summary, in the pattern forming method of the invention, at least three kinds of different photomask patterns are provided, at least two kinds of light sources with different wavelengths are used to transfer the at least three kinds of different photomask patterns to a material layer on a substrate, so as to form at least two patterns with different line widths. One of the at least two kinds of light sources with different wavelengths is a light source with a wavelength of 193 nm.

The present invention also provides a method of forming a pattern. First, a target pattern of a material layer is into a plurality of partial patterns. A mandrel pattern is formed between first partial patterns with a smallest critical dimension among the partial patterns by using a wet model 193 nm light source, and at least one second partial pattern is formed among the partial patterns by using at least one dry model light source. The dry model light source is a dry model 193 nm light source, a dry model 436 nm light source, a dry model 365 nm light source, or a dry model 248 nm light source.

In other words, in the embodiments of the invention, a target pattern to be formed is divided into a plurality of partial patterns, and partial patterns are respectively formed by multiple patterning processes with suitable exposure machines. Therefore, in the embodiments of the invention, the light sources with different wavelengths are selected according to the dimensions the respective partial patterns and the actual requirements. Since not all of the partial patterns are formed through the expensive advanced exposure machines, the cost on purchasing new machines and therefore the process cost can be significantly reduced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of forming a pattern, comprising:
providing N kinds of different photomask patterns; and
transferring the N kinds of different photomask patterns to a hard mask layer by using at least N−1 kinds of light sources with different wavelengths, so as to form a hard mask pattern, wherein one of the at least N−1 kinds of light sources with different wavelengths is a light source with a wavelength of 193 nm, and N is an integer of three or more.

2. The method of claim 1, wherein another of the at least N−1 kinds of light sources with different wavelengths is a light source with a wavelength of 436 nm (G-line), a light source with a wavelength of 365 nm (I-line), a light source with a wavelength of 248 nm or a light source with a wavelength shorter than 193 nm.

3. The method of claim 1, wherein the hard mask pattern has at least N−1 kinds of patterns with different line widths.

4. The method of claim 1, wherein the hard mask pattern comprises a first hard mask pattern and a second hard mask pattern, and a dimension of the first hard mask pattern is less than a dimension of the second hard mask pattern.

5. The method of claim 4, further comprising forming a sacrificial layer on the hard mask layer, wherein a method of forming the first hard mask pattern comprises:
forming a first patterned mask layer on the sacrificial layer by using a first photomask and a first light source with a wavelength of 193 nm;
performing a first etching process to transfer patterns of the first patterned mask layer to the sacrificial layer, so as to form at least one mandrel pattern;
forming a spacer loop around the mandrel pattern;
removing the mandrel pattern;
forming a second patterned mask layer by using a second photomask and a second light source, wherein the second patterned mask layer has an opening to expose a portion of the spacer loop at an end of the mandrel pattern;
performing a second etching process by using the second patterned mask layer as a mask, so as to break the spacer loop and form a plurality of spacers; and
performing a third etching process to the hard mask layer by using the plurality of spacers as a mask, so as to form the first hard mask pattern.

6. The method of claim 5, wherein a method of forming the second hard mask pattern comprises:
forming a third patterned mask layer on the hard mask layer by using a third photomask and a third light source; and
performing the third etching process to the hard mask layer by using the third patterned mask layer as a mask, so as to form the second hard mask pattern.

7. The method of claim 6, wherein the step of forming the third patterned mask layer is performed after the second etching process.

8. The method of claim 6, wherein the step of forming the third patterned mask layer is performed before the step of forming the second patterned mask layer.

9. The method of claim 4, wherein the second hard mask pattern is adjacent to and in contact with the first hard mask pattern.

10. The method of claim 9, wherein the hard mask pattern further comprises a third hard mask pattern spaced apart from the first hard mask pattern by a distance.

11. The method of claim 4, wherein the second hard mask pattern is spaced apart from the first hard mask pattern by a distance.

12. The method of claim 1, further comprising patterning a material layer under the hard mask pattern by using the hard mask pattern as a mask.

13. A method of forming a pattern, comprising:
dividing a target pattern of a material layer into a plurality of partial patterns; and
forming a mandrel pattern between first partial patterns with a smallest critical dimension among the partial patterns by using a first light source, and forming at least one second partial pattern among the partial patterns by using at least one second light source, wherein a wavelength of the first light source is less than a wavelength of the second light source, and one of the first and second light sources is a light source with a wavelength of 193 nm.

14. The method of claim 13, wherein another of the first and second light sources is a light source with a wavelength of 436 nm (G-line), a light source with a wavelength of 365 nm (I-line), a light source with a wavelength of 248 nm or a light source with a wavelength shorter than 193 nm.

15. A method of forming a pattern, comprising:
dividing a target pattern of a material layer into a plurality of partial patterns; and
forming a mandrel pattern between first partial patterns with a smallest critical dimension among the partial patterns by using a wet model 193 nm light source, and forming at least one second partial pattern among the partial patterns by using at least one dry model light source.

16. The method of claim 15, wherein the dry model light source is a dry model 193 nm light source, a dry model 436 nm light source, a dry model 365 nm light source, or a dry model 248 nm light source.
